(19) United States
(12) Patent Application Publication
(10) Pub. No.: US 2020/0411296 A1
(43) Pub. Date: Dec. 31, 2020

(54) SUBSTRATE PROCESSING APPARATUS

(71) Applicant: SEMES CO., LTD., Chungcheongnam-do (KR)

(72) Inventor: Jeong Seok Kang, Chungcheongnam-do (KR)

(21) Appl. No.: 16/911,531

(22) Filed: Jun. 25, 2020

(30) Foreign Application Priority Data
Jun. 27, 2019 (KR) 10-2019-0076846

(51) Int. Cl. H01J 37/32

(52) U.S. Cl. CPC H01J 37/32642; H01J 37/32715; H01J 2237/332; H01J 37/32082; H01J 2237/2007

(57) ABSTRACT

Provided is a substrate processing apparatus including a processing chamber configured to provide a processing space for a substrate, a chuck configured to support the substrate, and a focus ring disposed to surround an edge of the chuck. The focus ring includes a plurality of layers having different dielectric constants, and the dielectric constant and shape of each of the plurality of layers are determined to alleviate a change in electric field that is caused as the focus ring is etched.

### CROSS-REFERENCE TO RELATED APPLICATION

This application claims priority from Korean Patent Application No. 10-2019-0076846 filed on Jun. 27, 2019 in the Korean Intellectual Property Office, and all the benefits accruing therefrom under 35 U.S.C. 119, the contents of which in its entirety are herein incorporated by reference.

### BACKGROUND

### 1. Technical Field

The present disclosure relates to a substrate processing apparatus.

### 2. Description of the Related Art

A semiconductor device or a display device is fabricated through various processes including photolithography, etching, ashing, ion implantation, thin film deposition, and cleansing. Here, the photolithography process includes deposition, exposure, and development processes. A photoresist is deposited (i.e., deposition process), a circuit pattern is exposed onto the substrate on which the photoresist is formed (i.e., exposure process), and regions exposed on the substrate are selectively developed (i.e., development process).

Typically, plasma is used to etch the thin film formed on the wafer or substrate in the semiconductor fabrication process. The thin film may be etched by the plasma that is generated by the electric field produced in a processing chamber and bombards the wafer or substrate.

In order to increase the concentration of the plasma at the edge of the wafer or substrate, a ring member may be rigged along the edge of the wafer or substrate. The ring member may allow the plasma to be concentrated along the edge of the wafer or substrate, which makes it possible to achieve high quality etching on the edge as well as the center area of the wafer or substrate.

### SUMMARY

Aspects of the present disclosure provide a substrate processing apparatus.

However, aspects of the present disclosure are not restricted to the one set forth herein. The above and other aspects of the present disclosure will become more apparent to one of ordinary skill in the art to which the present disclosure pertains by referencing the detailed description of the present disclosure given below.

According to an aspect of the present disclosure, there is provided a substrate processing apparatus including a processing chamber configured to provide a processing space for a substrate, a chuck configured to support the substrate, and a focus ring disposed to surround an edge of the chuck, wherein the focus ring includes a plurality of layers having different dielectric constants, and wherein the dielectric constant and shape of each of the plurality of layers are determined to alleviate a change in electric field that is caused as the focus ring is etched.

The focus ring includes a base layer, and a reinforcement layer having a dielectric constant higher than that of the base layer and laminated on the base layer. The base layer includes a first plane part parallel to the ground and adjacent to the substrate, a second plane part parallel to the ground and far from the substrate in comparison with the first plane part, and a slope part inclined with respect to the ground and configured to connect the first plane part to the second plane part.

The slope part is formed such that a distance from the ground increases as a distance from the substrate increases.

The reinforcement layer is formed such that the second plane part is thicker than each of the first plane part and the slope part.

The reinforcement layer is formed such that its thickness increases as a distance from the substrate increases.

The reinforcement layer includes a plurality of sub-reinforcement layers having different dielectric constants.

Thicknesses of the plurality of sub-reinforcement layers and the base layer increase in the order from a top sub-reinforcement layer to the base layer.

Thicknesses of the plurality of sub-reinforcement layers and the base layer decrease in the order from a top sub-reinforcement layer to the base layer.

According to another aspect of the present disclosure, there is provided a substrate processing apparatus including a processing chamber configured to provide a processing space for a substrate, a base plate made of an insulator, a chuck configured to support the substrate, a main body provided between the base plate and the chuck, a focus ring disposed to surround an edge of the chuck, the focus ring including a base layer and a reinforcement layer having a dielectric constant higher than that of the base layer and laminated on the base layer, and a ring supporter configured to support the focus ring with respect to the base plate.

The base layer includes a first plane part parallel to the ground and adjacent to the substrate, a second plane part parallel to the ground and far from the substrate in comparison with the first plane part, and a slope part inclined with respect to the ground and configured to connect the first plane part to the second plane part.

The slope part is formed such that a distance from the ground increases as a distance from the substrate increases.

The reinforcement layer is formed such that the second plane part is thicker than each of the first plane part and the slope part.

The reinforcement layer is formed such that its thickness increases as a distance from the substrate increases.

The reinforcement layer includes a plurality of sub-reinforcement layers having different dielectric constants.

According to an aspect of the present disclosure, there is provided a substrate support including a base plate made of an insulator, a chuck configured to support the substrate, a main body provided between the base plate and the chuck, a focus ring disposed to surround an edge of the chuck, the focus ring including a base layer and a reinforcement layer having a dielectric constant higher than that of the base layer and laminated on the base layer, and a ring supporter configured to support the focus ring with respect to the base plate.

The base layer includes a first plane part parallel to the ground and adjacent to the substrate, a second plane part parallel to the ground and far from the substrate in comparison with the first plane part, and a slope part inclined with respect to the ground and configured to connect the first plane part to the second plane part.

The slope part is formed such that a distance from the ground increases as a distance from the substrate increases.

The reinforcement layer is formed such that the second plane part is thicker than each of the first plane part and the slope part.

The reinforcement layer is formed such that its thickness increases as a distance from the substrate increases.

The reinforcement layer includes a plurality of sub-reinforcement layers having different dielectric constants.

### BRIEF DESCRIPTION OF THE DRAWINGS

The above and other aspects and features of the present disclosure will become more apparent by describing in detail exemplary embodiments thereof with reference to the attached drawings, in which:

FIG. 1 is a cross-sectional view illustrating a substrate processing apparatus according to an embodiment of the present disclosure;

FIG. 2 is a perspective view illustrating the focus ring of FIG. 1;

FIG. 3 is a cross-sectional view of the focus ring, taken along line A-A′ of FIG. 2; and

FIGS. 4 to 8 are cross-sectional views of focus rings according to other embodiments of the present disclosure.

### DETAILED DESCRIPTION OF THE EMBODIMENTS

Hereinafter, preferred embodiments of the present disclosure will be described in detail with reference to the accompanying drawings. Advantages and features of the present disclosure and methods of accomplishing the same may be understood more readily by reference to the following detailed description of preferred embodiments and the accompanying drawings. The present disclosure may, however, be embodied in different forms and should not be construed as limited to the embodiments set forth herein. Rather, these embodiments are provided so that this disclosure will be thorough and complete, and will filly convey the scope of the invention to those skilled in the art. The same reference numbers indicate the same components throughout the specification.

It will also be understood that when a layer is referred to as being “on” another layer or substrate, it can be directly on the other layer or substrate, or intervening layers may also be present. In contrast, when an element is referred to as being “directly on” another element, there are no intervening elements present.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

Although the terms first, second, etc. may be used herein to describe various elements, components, regions, layers, and/or sections, these elements, components, regions, layers, and/or sections should not be limited by these terms. These terms are used to distinguish one element, component, region, layer, and/or section from another element, component, region, layer, and/or section. Thus, a first element, component, region, layer, and/or section discussed below could be termed a second element, component, region, layer, and/or section without departing from the teachings of the present disclosure.

The use of the terms “a” and “an” and “the” and similar referents in the context of describing the invention (especially in the context of the following claims) are to be construed to cover both the singular and the plural, unless otherwise indicated herein or clearly contradicted by context. The terms “comprising,” “having,” “including,” and “containing” are to be construed as open-ended terms (i.e., meaning “including, but not limited to,”) unless otherwise noted.

Unless defined otherwise, all technical and scientific terms used herein have the same meaning as commonly understood by one of ordinary skill in the art to which this invention belongs. It is noted that the use of any and all examples, or exemplary terms provided herein is intended merely to better illuminate the invention and is not a limitation on the scope of the invention unless otherwise specified. Further, unless defined otherwise, all terms defined in generally used dictionaries may not be overly interpreted.

Hereinafter, exemplary embodiments of the present disclosure will be described in detail with reference to the accompanying drawings. In the description with reference to the drawings, the same or corresponding elements are denoted by the same reference numerals, and a redundant description thereof will be omitted.

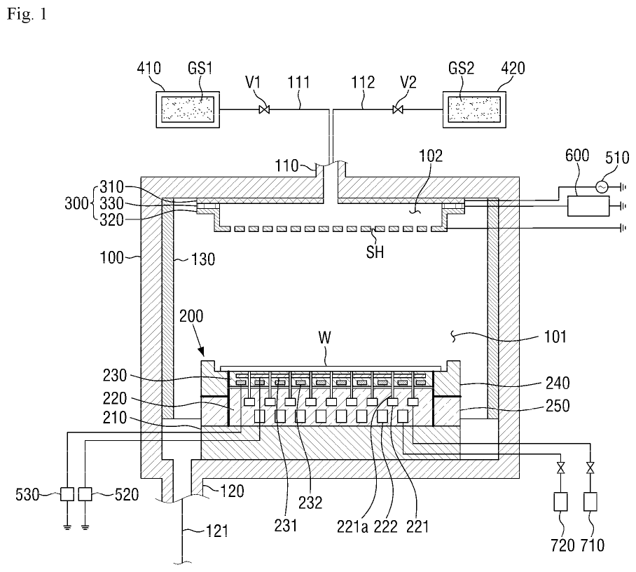

FIG. 1 is a cross-sectional view illustrating a substrate processing apparatus according to an embodiment of the present disclosure.

In reference to FIG. 1, the substrate processing apparatus 10 includes a processing chamber 100, a substrate support 200, a shower head 300, a first gas tank 410, a second gas tank 420, a first power supply unit 510, a second power supply unit 520, a third power supply unit 530, a heater 600, a heat medium supply unit 710, a refrigerant supply unit 720.

The processing chamber 10 may provide a processing space 101 for a substrate W. The bottom surface of the processing chamber is provided with an outlet 120. The outlet 120 is connected to a discharge line 121. The by-product and gas produced during the processes being carried out on the substrate W may be drained out through the outlet 120 and the discharge line 121.

The processing chamber 100 may be provided with a liner 130 in the inside thereof. The liner 130 may protect the inner surface of the processing chamber 100 against damage caused by arc discharge and prevent the impurities, which are produced during the process to the substrate W, from being deposited onto the inner surface of the processing chamber 100. For this purpose, the liner 130 may be mounted on the inner surface of the processing chamber 100 so as to surround the substrate support 200.

The substrate support 200 is responsible for supporting the substrate W. The substrate support 200 may be arranged at the bottom of the processing space 101.

The substrate support 200 includes a base plate 210, a main body 220, a chuck 230, a focus ring 240, and a ring supporter 250.

The base plate 210 is responsible for supporting the main body 220, the chuck 230, the focus ring 240, and the right supporter 250. The base plate 210 may be made of an insulator.

The main body 220 may be interposed between the base plate 210 and the chuck 230. The main body 220 may be provided with a heat medium circulation pipe 221 and a refrigerant circulation pipe 222 in the inside thereof. The heat medium circulation pipe 221 circulates a heat medium, and the refrigerant circulation pipe 222 circulates a refrigerant. The heat medium circulation pipe 221 and the refrigerant circulation pipe 222 may be arranged in a helical shape in the inside of the main body 220. The main body 220 may be heated by the heat medium circulating through the heat medium circulation pipe 221 and cooled by the refrigerant circulating through the refrigerant circulation pipe 222.

The main body 220 may be made of metal. The chuck 230 that is tightly joined to the main body 220 may be affected by the temperature of the main body 220. The chuck 230 may be heated as the main body 220 is heated and cooled as the main body 220 is cooled.

A heat medium supply pipe 221a may be connected to the heat medium circulation pipe 221 in order to supply the heat medium to the upper part of the chuck 230. The heat medium may be supplied to the substrate W through the heat medium supply pipe 221a.

The heat medium supply unit 710 may supply the heat medium through the heat medium circulation pipe 221, and the refrigerant supply unit 720 may supply the refrigerant through the refrigerant circulation pipe 222. In the present disclosure, the heat medium may be, but is not limited to, helium gas.

The chuck 230 may be responsible for supporting the substrate W. In the present disclosure, the chuck 230 may be an electrostatic chuck. That is, the chuck 230 may adsorb the substrate W with an electrostatic force. Although the present disclosure is directed to the electrostatic check, the chuck 230 may be configured to hold and support the substrate W in a mechanical manner. Hereinafter, the description is directed to the case where the chuck 230 is the electrostatic chuck.

The body of the chuck may be a dielectric material. The chuck 230 may be provided with an electrostatic electrode 231 and a heating unit 232 in the inside thereof. The electrostatic electrode 231 may be electrically connected to the second power supply unit 520. The electrostatic electrode 231 may generate an electrostatic force with the power supplied from the second power supply unit 520. The substrate W is adsorbed onto the chuck 230 by the corresponding electrostatic force.

The heating unit 232 may be electrically connected to the third power supply unit 530. The heating unit 232 may be heated by the power supplied from the third power supply unit 530. The heat may be transferred from the heating unit 232 to the substrate W. The substrate W may be maintained at a predetermined temperature with the heat from the heating unit 232. The heating unit 232 may be provided to be arranged in a helical shape in the inside of the chuck 230.

The second power supply unit 520 may supply power to the electrostatic electrode 231, and the third power supply 530 may supply power to the heating unit 232. Here, the power being supplied by the second power supply unit 520 may be a direct current power.

The focus ring 240 may be provided in the form of a ring surrounding the edge of the chuck 230. The focus ring 240 is responsible for adjusting the electric field produced around the edge of the chuck 230. For this purpose, the focus ring 240 may be made of a material having a predetermined dielectric constant.

The ring supporter 250 may support the focus ring 240 on the base plate 210. The focus ring 240 may be maintained at a predetermined height from the base plate 210 by the ring supporter 250 so as to surround the edge of the chuck 230. The ring supporter 250 may be made of an insulator.

The focus ring 240 may be etched during the plasma-assisted process onto the substrate W. Considering that the focus ring 240 has a predetermined dielectric constant to adjust the electric field generated around the edge of the chuck 230 as described above, if the focus ring 240 is etched, this may change the dielectric constant, which leads to a change in shape of the electric field. The electric field may determine an incidence direction of the plasma onto the substrate W. As the electric field varies in shape, the incidence direction of the plasma onto the substrate W varies, which may disturb correctly carrying out the process on the substrate W.

If the focus ring 240 cannot generate the proper electric field, it may be replaced by a new one. Although it may be possible to increase the use period of the focus ring 240 by increasing the thickness of the focus ring 240, an excessively thick focus ring may also generate an improper electric field.

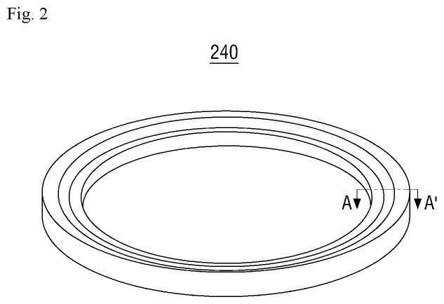

In this regard, the focus ring 240 may be made of a plurality of layers according to an embodiment of the present disclosure. The dielectric constant and shape of each of the plurality of layers may be determined in a way of alleviating the change of the electric field that is caused as the focus ring 240 is etched. For example, the individual layers have different dielectric constants such that the focus ring 240 may generate, even when its top layer is etched to be removed, the electric field similar to that before the removal of the top layer with the reduced thickness. A detailed description is made of the focus ring 240 later with reference to FIGS. 2 to 7.

The shower head 300 is responsible for spraying, onto the substrate W, a process gas for processing the substrate W. The shower head 300 may be arranged at the top part in the processing space 101. The process gas sprayed from the shower head 300 reaches down onto the substrate W.

In the present disclosure, the process gas for use in processing the substrate W may include a first process gas GS1 and a second process gas GS2. The first process gas GS1 and the second process gas GS2 may flow into the processing space 101 through a process gas inlet 110. A first inlet line 111 and a second inlet line may be connected to the process gas inlet 110. The first process gas GS1 may flow into the processing space 101 through the first inlet line 111, and the second process gas GS2 may flow into the processing space 101 through the second inlet line 112.

The first process gas GS1 and the second process GS2 may mutually react to be sprayed onto the substrate W. For example, the first process gas GS1 may act as a role of reaction gas, and the second process gas GS2 may act as a role of source gas. That is, the first process gas GS1 may excite the second process gas GS2. The first process gas GS1 may be converted to plasma and then react to the second process gas GS2. Hereinafter, the plasma generated with the first process gas GS1 is referred to as first plasma.

The shower head 300 may spray the first process gas GS1 and the second process gas GS2 onto the substrate W. The first process gas GS1 and the second process gas GS2 may be sprayed in order. The first process gas GS1 and the second process gas GS2 sprayed from the shower head 300 may collide and react to each other. Then, the second process gas GS2 excited by the first process GS1 may reach down onto the substrate W to carry out the process on the substrate W. For example, the excited second process gas GS2 may be deposited to form a thin film on the substrate W.

The shower head 300 may include an electrode plate 310, a spray member 320, and a ring-shaped dielectric plate 330. The electrode plate 310 may receive an input of RF power. The RF power may be supplied from the first power supply unit 510. The electrode plate 310 may have a broad surface that is tightly joined to the upper surface of the processing chamber 100.

The spray member 320 may be arranged on the low part of the electrode plate 310 to spray the first process gas GS1 and the second process gas GS2. For this purpose, the spray member 320 may be provided with spray holes SH for spraying the first process gas GS1 and the second process gas GS2. The first process gas GS1 and the second process gas GS2 may flow into the processing chamber 101 through the spray holes SH.

The ring-shaped dielectric plate 330 may electrically separate the electrode plate 310 and the spray member 320. For this purpose, the ring-shaped dielectric plate 330 may be made of a dielectric material and disposed between the electrode plate 310 and the spray member 320. The ring-shaped dielectric plate 330 may be arranged circumferentially around and between the electrode plate 310 and the spray member 320. The electrode plate 310 and the spray member 320 may also be distanced from each other by a predetermined distance with the exception of the edges thereof. As a consequence, a predetermined space may be formed between the electrode plate 310 and the spray member 320. Hereinafter, the space formed between the electrode plate 310 and the spray member 320 is referred to as gas processing space 102.

The gas processing space 102 may communicate with the holes SH.

The second process gas GS2 being supplied from the spray member 320 is diffused in the gas processing space 102 so as to be discharged through the spray holes SH. Hereinafter, the plasma generated with the second process gas GS2 is referred to as second plasma. The second process gas GS2 may be silane SiH4. The second plasma may include hydrogen plasma.

The first gas tank 410 may contain the first process gas GS1, and the second gas tank 420 may contain the second process gas GS2. The first inlet line 111 connecting the first gas tank 410 and the process gas inlet 110 may be provided with a first valve V1, and likewise the second inlet line 112 connecting the second gas tank 420 and the process gas inlet 110 may be provided with a first value V2. The first value V1 and the second value V2 may be opened during the process on the substrate W such that the first process gas GS1 and the second process gas GS2 are injected into the processing space 101 of the processing chamber 100. After the process on the substrate W is completed, the first value V1 and the second valve V2 are closed to stop the first process gas GS1 and the second process gas GS2 from being injected into the inside of the processing chamber 100.

The heater 600 is responsible for heating the spray member 320. The second process gas GS2 injected into the spray member 320 may be heated and then sprayed through the spray holes SH. As the second process gas GS2 is heated, the reaction to the first plasma may become more vigorous.

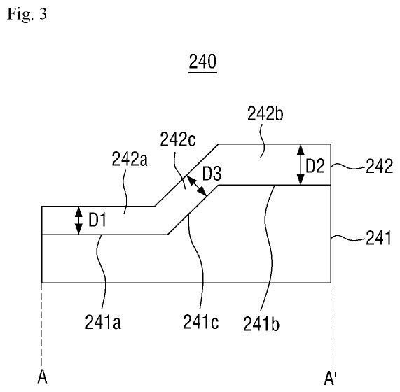

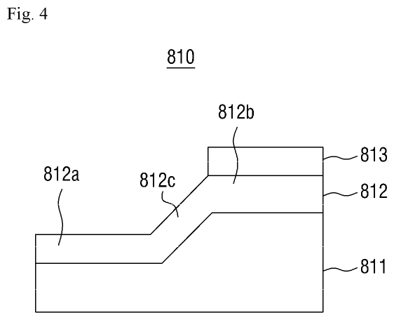

FIG. 2 is a perspective view illustrating the focus ring of FIG. 1. FIG. 3 is a cross-sectional view of the focus ring, taken along line A-A′ of FIG. 2. FIGS. 4 to 8 are cross-sectional views of focus rings according to other embodiments of the present disclosure.

In reference to FIGS. 2 and 3, the focus ring 240 includes a base layer 241 and a reinforcement layer 242.

The base layer 241 and the reinforcement layer 242 have different dielectric constants, and the reinforcement layer 242 may be laminated on the base layer 241. In detail, the reinforcement layer 242 may be made of a material having a dielectric constant higher than that of the base layer 241.

The base layer 241 may include a first plane part 241a, a second plane part 241b, and a slope part 241c. The first plane part 241 may be in parallel with the ground and adjoin the substrate W. The second plane part 241b may be in parallel with the ground and far from the substrate W in comparison with the first plane part 241a. The slope part 241c may be inclined with respect to the ground to connect the first plane part 241a to the second plane part 241b.

The slope part 241c may be formed such that the distance from the ground increases as the distance from the substrate W increases. This means that the second plane part 241b has a height higher than that of the first plane part 241a.

The reinforcement layer 242 may be laminated over the first plane part 241a, the second plane part 241b, and the slope part 241c. The reinforcement layer 242 may be formed such that the second plane part 241b is thicker than each of the first plane part 241 and the slope part 241c. This means that the thickness D2 of the reinforcement layer deposited on the second plane part 241b (hereinafter, second plane layer 242b) is thicker than the thicknesses D1 and D3 of the reinforcement layer deposited on the first plane part 241a and the slope part 241c (hereinafter, referred to as first plane layer 242a and slope layer 242c).

In the case where the focus ring 240 starts being etched during the process to the substrate W, the second plane layer 242b may start being etched prior to the first plane layer 242a and the slop layer 242c. Because of the second plane layer 242b is formed to be thicker than the first plane layer 242a, the first and second plane layers 242a and 242b may be completely etched out substantially at the same time. This may make it possible to prevent a change of the electric field that may occur in the case where the reinforcement layer 242 and the base layer 241 are simultaneously exposed to the processing space 101.

In reference to FIG. 4, the focus ring 810 may include a base layer 811, a reinforcement layer 812, and an additional reinforcement layer 813.

The reinforcement layer 812 may include a first plane layer 812a, a second plane layer 812b, a slop layer 812c. The additional reinforcement layer 813 may be deposited on the second plane layer 812b. The dielectric constant of the additional reinforcement layer 813 may be equal to or higher than that of the reinforcement layer 812. In the case where the focus ring 810 starts being etched during the process on the substrate W, the additional reinforcement layer 813 may start being first etched. Because of the existence of the second plane layer 812b even after the additional reinforcement layer 813 being completely etched out, the electric field change caused by the etching of the focus ring 810 may be alleviated.

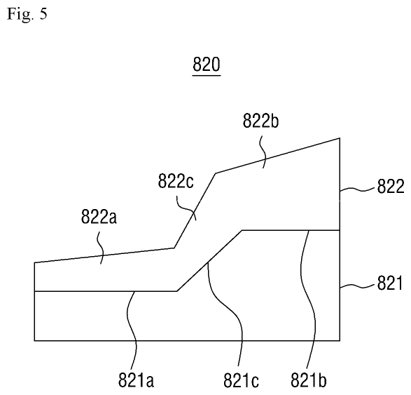

In reference to FIG. 5, the focus ring 820 may include a base layer 821 and a reinforcement layer 822.

The reinforcement layer 822 may include a first plane layer 822a, a second plane layer 822b, and a slope layer 822c. The reinforcement layer 822 may be formed such that the thickness thereof increases as the distance from the substrate W increases. The first plane layer 822a, the second plane layer 822b, and the slope layer 822c may each become thicker as the distance from the substrate W increases on each of a first plane layer 821a, a second plane layer 821b, and a slop layer 821c of the base layer 821.

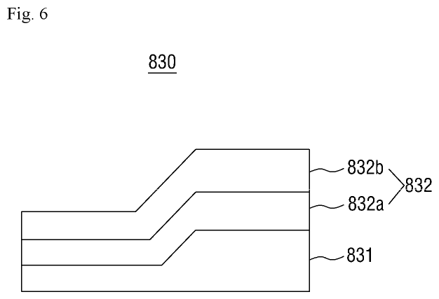

In reference to FIG. 6, the focus ring 830 may include a base layer 831 and a reinforcement layer 832.

The reinforcement layer 832 may include a plurality of sub-reinforcement layers 832a and 832b that have different dielectric constants. The top sub-reinforcement layer 832b of the plurality of sub-reinforcement layers 832a and 832b may have the highest dielectric constant, and the dielectric constant may decreases as going down. That is, the top sub-reinforcement layer 832b has the highest dielectric constant, the base layer 831 has the lowest dielectric constant, and the intermediate sub-reinforcement layer 832a may have an intermediate dielectric constant.

Although it is depicted in FIG. 6 that the reinforcement layer 832 includes two sub-reinforcement layers 832a and 832b, the reinforcement layer 832 may include three or more sub-reinforcement layers according to some embodiments of the present disclosure.

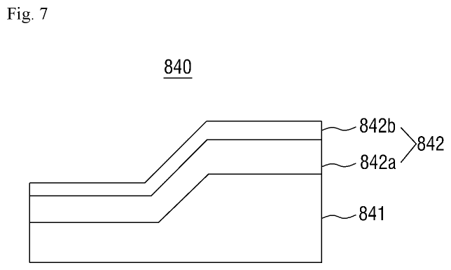

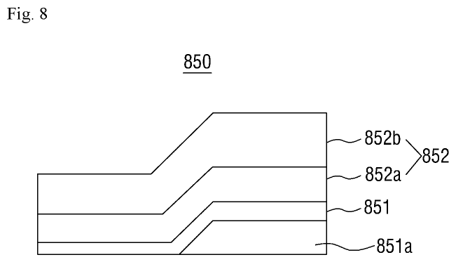

The sub-reinforcement layers 832a and 832b may be identical in thickness with each other as shown in FIG. 6 or different in thickness from each other as shown in FIGS. 7 and 8.

In reference to FIGS. 7 and 8, a focus ring 840, 850 may include a base layer 841, 851 and a reinforcement layer 842, 852.

The reinforcement layer 842, 852 may have a plurality of sub-reinforcement layers 842a, 842b, 852a, 852b that have different dielectric constants. The top sub-reinforcement layer 842b and 852b of the plurality of sub-reinforcement layers 842a, 842b, 852a, 852b may have the highest dielectric constant, and the dielectric constant may decrease as going down.

As shown in FIG. 7, the thicknesses of the plurality of the sub-reinforcement layers 842a and 842b and the base layer 841 may increase in the order from the top sub-reinforcement layer 842b to the base layer 841. As shown in FIG. 8, the thicknesses of the plurality of the sub-reinforcement layers 852a and 852b and the base layer 851 may decrease in the order from the top sub-reinforcement layer 852b to the base layer 851.

In order for the base layer 851 to have a thickness thinner than that of each of the sub-reinforcement layers 852a and 852b, another base layer 851a having a dielectric constant different from that of the base layer 851 may be provided below the base layer 851.

The dielectric constant and thickness of each of the base layers 831, 841, and 851 and the sub-reinforcement layers 832a, 832b, 842a, 842b, 852a, and 852b may be variously determined according to the processing environment of the processing chamber 100.

In concluding the detailed description, those skilled in the art will appreciate that many variations and modifications can be made to the preferred embodiments without substantially departing from the principles of the present disclosure. Therefore, the disclosed preferred embodiments of the invention are used in a generic and descriptive sense only and not for purposes of limitation.

What is claimed is:

1. A substrate processing apparatus comprising:
a processing chamber configured to provide a processing space for a substrate;
a chuck configured to support the substrate; and
a focus ring disposed to surround an edge of the chuck,
wherein the focus ring includes a plurality of layers having different dielectric constants, and
wherein the dielectric constant and shape of each of the plurality of layers are determined to alleviate a change in electric field that is caused as the focus ring is etched.

2. The substrate processing apparatus of claim 1, wherein the focus ring includes:
a base layer; and
a reinforcement layer having a dielectric constant higher than that of the base layer and laminated on the base layer, and
wherein the base layer includes:
a first plane part parallel to the ground and adjacent to the substrate;
a second plane part parallel to the ground and far from the substrate in comparison with the first plane part; and
a slope part inclined with respect to the ground and configured to connect the first plane part to the second plane part.

3. The substrate processing apparatus of claim 2, wherein the slope part is formed such that a distance from the ground increases as a distance from the substrate increases.

4. The substrate processing apparatus of claim 2, wherein the reinforcement layer is formed such that the second plane part is thicker than each of the first plane part and the slope part.

5. The substrate processing apparatus of claim 2, wherein the reinforcement layer is formed such that its thickness increases as a distance from the substrate increases.

6. The substrate processing apparatus of claim 2, wherein the reinforcement layer includes a plurality of sub-reinforcement layers having different dielectric constants.

7. The substrate processing apparatus of claim 6, wherein thicknesses of the plurality of sub-reinforcement layers and the base layer increase in the order from a top sub-reinforcement layer to the base layer.

8. The substrate processing apparatus of claim 6, wherein thicknesses of the plurality of sub-reinforcement layers and the base layer decrease in the order from a top sub-reinforcement layer to the base layer.

9. A substrate processing apparatus comprising:
a processing chamber configured to provide a processing space for a substrate;
a base plate made of an insulator;
a chuck configured to support the substrate;
a main body provided between the base plate and the chuck;
a focus ring disposed to surround an edge of the chuck, the focus ring including a base layer and a reinforcement layer having a dielectric constant higher than that of the base layer and laminated on the base layer; and
a ring supporter configured to support the focus ring with respect to the base plate.

10. The substrate processing apparatus of claim 9, wherein the base layer includes:
a first plane part parallel to the ground and adjacent to the substrate;
a second plane part parallel to the ground and far from the substrate in comparison with the first plane part; and
a slope part inclined with respect to the ground and configured to connect the first plane part to the second plane part.

11. The substrate processing apparatus of claim 10, wherein the slope part is formed such that a distance from the ground increases as a distance from the substrate increases.

12. The substrate processing apparatus of claim 10, wherein the reinforcement layer is formed such that the second plane part is thicker than each of the first plane part and the slope part.

13. The substrate processing apparatus of claim 10, wherein the reinforcement layer is formed such that its thickness increases as a distance from the substrate increases.

14. The substrate processing apparatus of claim 10, wherein the reinforcement layer includes a plurality of sub-reinforcement layers having different dielectric constants.

15. A substrate support comprising:
a base plate made of an insulator;
a chuck configured to support the substrate;
a main body provided between the base plate and the chuck;
a focus ring disposed to surround an edge of the chuck, the focus ring including a base layer and a reinforcement layer having a dielectric constant higher than that of the base layer and laminated on the base layer; and
a ring supporter configured to support the focus ring with respect to the base plate.

16. The substrate support of claim 15, wherein the base layer includes:
a first plane part parallel to the ground and adjacent to the substrate;
a second plane part parallel to the ground and far from the substrate in comparison with the first plane part; and
a slope part inclined with respect to the ground and configured to connect the first plane part to the second plane part.

17. The substrate support of claim 16, wherein the slope part is formed such that a distance from the ground increases as a distance from the substrate increases.

18. The substrate support of claim 16, wherein the reinforcement layer is formed such that the second plane part is thicker than each of the first plane part and the slope part.

19. The substrate support of claim 16, wherein the reinforcement layer is formed such that its thickness increases as a distance from the substrate increases.

20. The substrate support of claim 16, wherein the reinforcement layer includes a plurality of sub-reinforcement layers having different dielectric constants.
